(19) United States
(12) Patent Application Publication
(10) Pub. No.: US 2008/0087949 A1
(43) Pub. Date: Apr. 17, 2008

(54) SEMICONDUCTOR DEVICE AND METHOD OF MANUFACTURING THE SAME

(75) Inventors: Michiaki MARUOKA, Ohtsu-shi (JP); Kimimori HAMADA, Toyota-shi (JP); Hidefumi TAKAYA, Nishikamo-gun (JP)

Correspondence Address: SUGHRUE MION, PLLC, 2100 PENNSYLVANIA AVENUE, N.W., SUITE 800, WASHINGTON, DC, 20037, US

(73) Assignees: NEC ELECTRONICS CORPORATION, Kanagawa (JP); TOYOTA JIDOSHA KABUSHIKI KAISHA, Toyota-shi (JP)

(21) Appl. No.: 11/854,183

(22) Filed: Sep. 12, 2007

(30) Foreign Application Priority Data
Oct. 17, 2006 (JP) 2006-282217

(51) Int. Cl. H01L 29/78; H01L 21/336

(52) U.S. Cl. 257/330; 257/334; 438/272; 257/E29.262; 257/E21.41

(57) ABSTRACT

A p-type epitaxial layer is formed on an n+-type substrate and then a buried n-type region is formed at a boundary between the n+-type substrate and the p-type epitaxial layer by ion implantation. Subsequently, a trench is formed so as to reach the n+-type substrate, passing through the p-type epitaxial layer and the buried n-type region. Then, a gate electrode is formed so as to deeply extend into the trench, i.e. to a position opposed to the buried n-type region. In a vertical MOSFET with this structure, when a positive voltage is applied to the gate electrode, an accumulation layer with a low resistance is formed in the buried n-type region, thereby reducing an on-resistance.

This application is based upon and claims the benefit of priority from Japanese patent application No. 2006-282217, filed on Oct. 17, 2006, the disclosure of which is incorporated herein in its entirety by reference.

### BACKGROUND OF THE INVENTION

This invention relates to a semiconductor device and its manufacturing method and, in particular, relates to a semiconductor device including a vertical MOSFET with a gate electrode buried in a trench and a method of manufacturing such a semiconductor device.

In recent years, there is a tendency that low breakdown voltage power semiconductor devices are required in electronic devices for automobiles and the like and, as such low breakdown voltage power semiconductor devices, there have been proposed semiconductor devices each arranged with a large number of vertical field-effect transistors (hereinafter referred to as “vertical MOSFETs”), for example, several tens of thousands to several millions of vertical MOSFETs.

In this case, since all the vertical MOSFETs forming cells of the semiconductor device are arranged parallel to each other between the drain and source, a large amount of current is allowed to flow. On the other hand, as the important factors for evaluating the vertical MOSFET, there are an avalanche breakdown voltage and an on-resistance Ron. Herein, the avalanche breakdown voltage is an element breakdown voltage at which breakdown occurs when the voltage is applied across the drain and source with the gate and source shorted together, and will hereinbelow be given as BVDSS.

The channel resistance of each of the vertical MOSFETs forming the low breakdown voltage power semiconductor device can be largely reduced by miniaturization. However, a reduction in resistance is limited only the miniaturization. This is because the resistance of a semiconductor layer, i.e. an epitaxial layer, provided for obtaining a predetermined BVDSS is essential apart from the channel resistance. Under these circumstances, there is required a structure and manufacturing method of a low breakdown voltage power MOSFET that enables a further reduction in resistance.

Patent Document 1 (Japanese Unexamined Patent Application Publication (JP-A) No. 2004-56003) discloses a semiconductor device formed by vertical MOSFETs. The structure of each vertical MOSFET shown in Patent Document 1 will be specifically described with reference to FIG. 2 of Patent Document 1.

The vertical MOSFET shown in FIG. 2 of Patent Document 1 comprises a substrate forming an n+-type drain region, a drift region formed by an n-type epitaxial layer on the substrate, a p-type body region (base region) formed so as to contact the drift region, and a source region formed on the body region. Further, a trench is formed so as to extend from the surface of the source region to reach the drain region (i.e. the substrate), passing through the body region and the drift region. Further, a gate oxide film having a thickness of 2000 Å or more is formed in the trench and a gate electrode made of polysilicon is buried in the gate oxide film.

In the structure shown in Patent Document 1, since a depletion layer extends to the side of the n-type epitaxial layer serving as the drift region at the time of BVDSS measurement, there is no problem with respect to BVDSS. However, in order to turn on the MOSFET shown in Patent Document 1, it is necessary to apply a voltage of 20V or more to the gate electrode. With this structure, a reduction in on-resistance Ron is limited due to a resistance of the n-type epitaxial layer itself serving as the drift region when the current flows in the n-type epitaxial layer.

Patent Document 2 (Japanese Unexamined Patent Application Publication (JP-A) No. 2005-302925) discloses a vertical MOSFET that can reduce an on-resistance Ron without lowering a breakdown voltage between the source and drain. The vertical MOSFET shown in Patent Document 2 comprises a substrate forming an n+-drain region, an n−-type drift region formed on the substrate, a p-type base region formed on the drift region, and an n+-type source region formed on the base region. Further, a trench is formed so as to extend from the surface of the source region to reach the substrate forming the drain region, passing through the base region and the drift region. An insulating film (oxide film) is buried in the trench adjacent to the n+-type region serving as the substrate and the n−-type region serving as the drift region. Further, in a region, adjacent to the base region and the source region, in the trench, a gate oxide film is formed and a gate electrode made of polysilicon is buried. The gate electrode is provided so as not to reach the n−-type drift region, but to face substantially only the base region.

In the MOSFET thus structured, since a depletion layer extends to the n−-type drift region at the time of BVDSS measurement, there is no problem with respect to BVDSS and, further, Crss (mirror capacitance) can also be reduced. However, since the n−-type drift region is divided by the trench so as to be small and further an accumulation layer cannot be formed, the on-resistance Ron generated when the MOSFET is turned on cannot be further reduced.

Patent Document 3 (Japanese Unexamined Patent Application Publication (JP-A) No. 2000-164869) discloses a vertical MOSFET that can reduce an on-resistance and, further, can reduce possibility of punch-through breakdown without increasing a threshold voltage. The vertical MOSFET shown in Patent Document 3 comprises an n+-type substrate, a p-type epitaxial region formed on the n+-type substrate, a trench formed in the p-type epitaxial region, an oxide layer formed in the trench along its side wall and bottom surface, a gate electrode buried in the oxide layer, and an n+-type source region formed adjacent to an upper surface of the p-type epitaxial region and the side wall of the trench.

Further, in FIG. 18 of Patent Document 3, there is also shown a structure in which a trench extends from the silicon surface to reach an n+-type substrate, passing through a p-type epitaxial region.

On the other hand, in FIG. 3 of Patent Document 3, there is shown an example in which an n-type drain region forming a junction is formed between the bottom of the trench and the n+-type substrate. This n-type drain region is formed by, after forming the trench at a portion of the p-type epitaxial region, implanting phosphorus into the p-type epitaxial region at the bottom of the trench at a predetermined energy, wherein at least 75% and preferably 90% of the n-type drain region is disposed just under the trench.

When, like in this example, the p-type epitaxial region is formed on the n-type drain region and the trench is formed within the p-type epitaxial region, the n-type drain region is interposed between the bottom of the trench and the n+-type substrate. With the structure shown in FIG. 3 of Patent Document 3, it is possible to form an effective depletion layer at a junction between the n-type drain region and the p-type epitaxial region at the time of BVDSS measurement.

In Patent Document 1, there is a problem that if the gate oxide film is reduced in thickness for low-voltage operation, BVDSS is lowered. Further, although it is described in Patent Document 1 to raise the driving voltage to 20V, it is difficult to actually fabricate a control IC capable of raising the driving voltage to 20V and thus there is no practicality as a power MOSFET.

In order to realize a low on-resistance Ron for a miniaturized power MOSFET, it is most important to reduce a resistance of an n-type epitaxial region. However, in Patent Document 2, there is a problem that, as described above, the resistance of the n-type epitaxial region can hardly be reduced.

In the MOSFET with the structure in which, as shown in FIG. 18 of Patent Document 3, the p-type epitaxial region is formed on the n+-type substrate and the trench extends from the silicon surface to reach the n+-type substrate, passing through the p-type epitaxial region, there is a problem that a depletion layer does not extend at the time of BVDSS measurement and thus an effective BVDSS cannot be obtained. Further, in the MOSFET with the structure in which, as shown in FIG. 3 of Patent Document 3, the p-type epitaxial region is formed on the n-type drain region and the trench is formed within the p-type epitaxial region so that the n-type drain region is interposed between the trench and the n+-type substrate, the resistance of the n-type drain region cannot be ignored and thus the reduction in on-resistance Ron is limited.

In any of Patent Documents 1 to 3, the reduction in on-resistance Ron is limited or, conversely, the increase in BVDSS is limited. Therefore, it is difficult to increase the BVDSS and, at the same time, reduce the on-resistance Ron.

### SUMMARY OF THE INVENTION

The present invention seeks to solve one or more of the above problems, or to improve upon those problems at least in part providing a semiconductor device that can solve the foregoing problems and simultaneously enables an increase in BVDSS and a reduction in on-resistance, and to further provide a method of manufacturing such a semiconductor device.

According to a first mode of this invention, there is obtained a semiconductor device comprising a substrate of a first conductivity type, a semiconductor layer of a second conductivity type opposite to the first conductivity type on the substrate, a buried region of the first conductivity type formed on a boundary between the substrate and the semiconductor layer, a trench that passes through the semiconductor layer and the buried region and that reaches to the substrate, a gate insulation film on an inside of the trench, and a gate electrode surrounded by the gate insulation film, wherein the gate electrode has a portion faced with the semiconductor layer through the gate insulation film and a portion faced with the buried region through the gate insulation film.

### BRIEF DESCRIPTION OF THE DRAWINGS

FIG. 1 is a sectional view for explaining a process of a manufacturing method of a field-effect transistor (MOSFET) according to a first exemplary embodiment of this invention;

FIG. 2 is a sectional view for explaining a process subsequent to the process shown in FIG. 1;

FIG. 3 is a sectional view for explaining a process subsequent to the process shown in FIG. 2;

FIG. 4 is a sectional view for explaining the structure of the field-effect transistor according to the first exemplary embodiment of this invention obtained through the process shown in FIG. 3;

FIG. 5 is a sectional view for explaining the operation of the field-effect transistor shown in FIG. 4; and

FIG. 6 is a sectional view for explaining a field-effect transistor according to a second exemplary embodiment of this invention.

### DESCRIPTION OF THE PREFERRED EXEMPLARY EMBODIMENTS

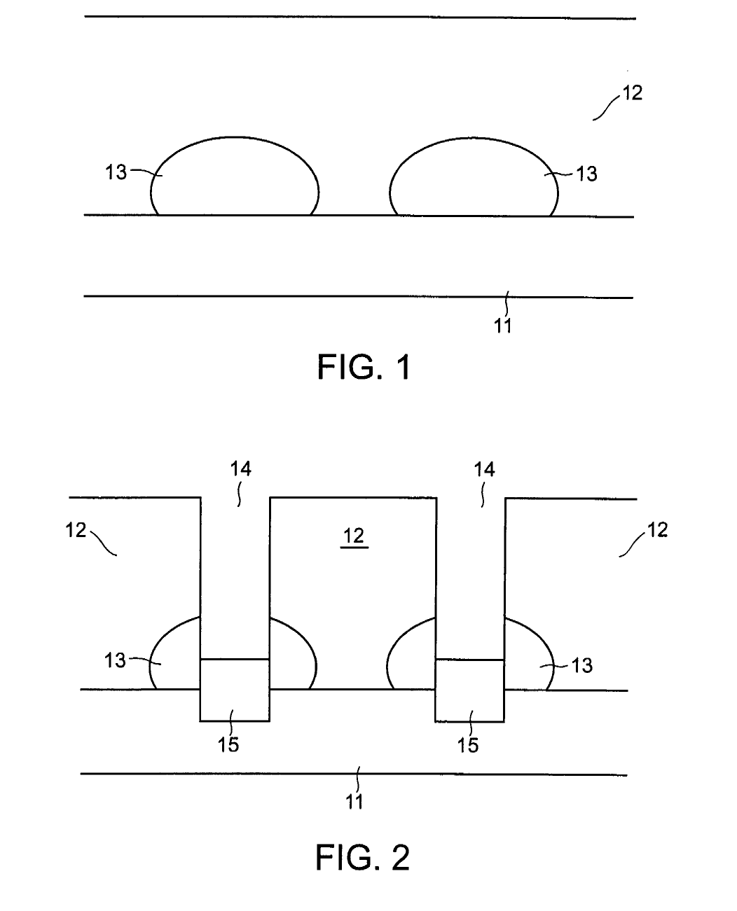

Referring to FIGS. 1 to 4, description will be made about a manufacturing method of a semiconductor device according to a first exemplary embodiment of this invention in the order of processes. As shown in FIG. 1, a p-type epitaxial layer 12 is at first formed by epitaxial growth on the surface of an n+-type silicon single-crystal substrate 11. For example, when a power MOSFET of a low breakdown voltage, such as a BVDSS of 60V or less, is manufactured, the p-type epitaxial layer 12 may have a resistivity of 0.3 to 0.8Ω·cm and a thickness of about 1.5 to 2.5 μm.

Then, after a predetermined region of the surface of the p-type epitaxial layer 12 is masked with a photoresist mask and is subjected to patterning, high-energy ion implantation is carried out so as to embed or bury n-type regions 13. As shown in FIG. 1 the n-type regions 13 are buried by this ion implantation at mutually spaced-apart positions within the p-type epitaxial layer 12 at a boundary between the n+-type silicon substrate 11 and the p-type epitaxial layer 12. For example, when the p-type epitaxial layer 12 has a thickness of 2 μm, phosphorus of 1E13 to 1E14 atoms/cm² is ion-implanted at energy of 1400 KeV. Thus, the buried n-type regions 13 are formed at a predetermined distance left therebetween at the boundary between the n+-type substrate 11 and the p-type epitaxial layer 12.

In the illustrated exemplary embodiment, junctions among the buried n-type regions 13 and the p-type epitaxial layer 12 may form so-called super junctions.

After the formation of the buried n-type regions 13, as shown in FIG. 2, trenches 14 are formed which pass through the middle of the corresponding buried n-type regions 13 and which reach to the n+-type substrate 11. The trenches 14 which pass through the buried n-type region 13 and reach the n+-type substrate 11 as described above are one of features of this invention. After the formation of the trenches 14, an LP-NSG (low pressure-non-doped silicate glass) film is covered on the trenches 14 and the surface of the p-type epitaxial layer 12. After the NSG film is formed in the trenches 14 and on the surface of the p-type epitaxial layer 12, the NSG film is subjected to etchback and overetching. In this event, the NSG film is etched in each trench 14 to a position adjacent to the corresponding buried n-type region 13 as shown in FIG. 2. As a result, a buried insulation film 15 of NSG is left in a bottom of each trench 14.

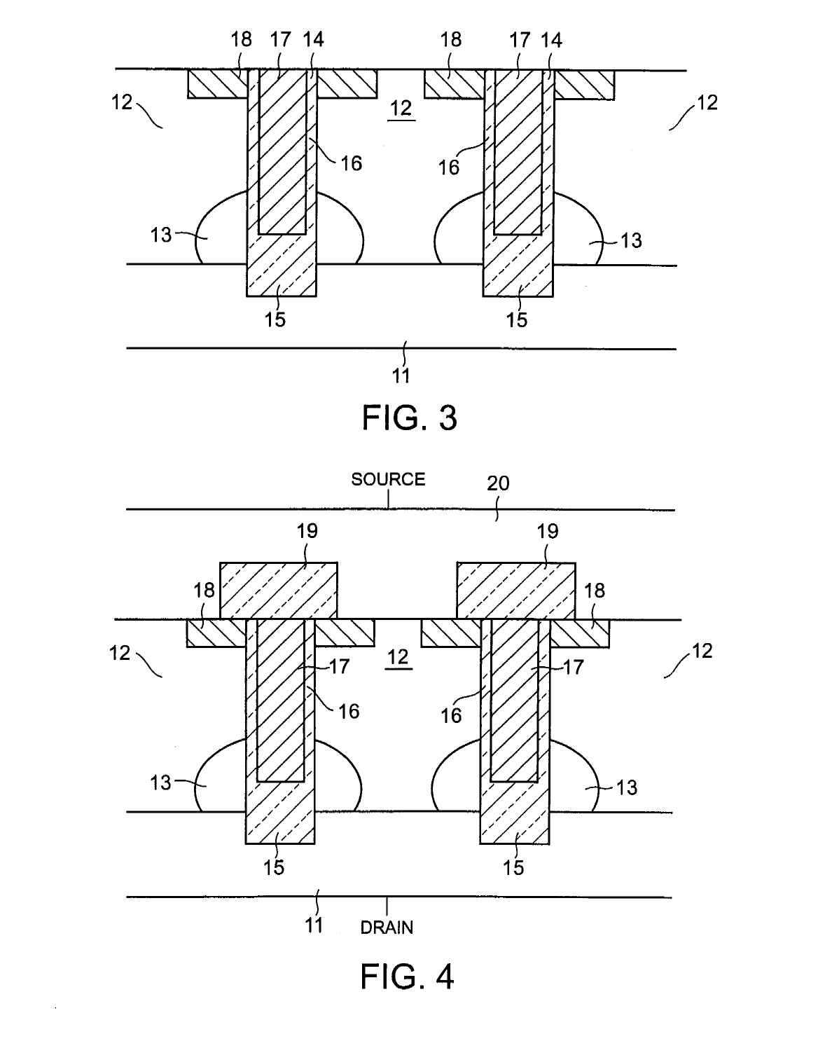

Then, as shown in FIG. 3, thin gate oxide films 16 of, for example, 300 to 1000 Å thick are each formed along a channel forming region (i.e. each side wall of the corresponding trenchs). As shown in FIG. 3, each gate oxide film 16 is extended to the corresponding buried insulating film 15 and is contacted with the p-type epitaxial layer 12 and is partially contacted with the corresponding buried n-type regions 13. Thus, it is to be noted that a gate insulation film is formed by the thin gate oxide film 16 and the thick buried insulating film 15 left on the bottom of each trench 14.

Subsequently, polysilicon is grown on the gate insulation film and the surface of the p-type epitaxial layer 12 and etched back after the growth of the polysilicon to be left in the respective trenches 14 so as to form gate electrodes 17. Thus, the gate electrodes 17 of polysilicon are left in the trenches 14. As shown in FIG. 3, it is readily understood that the gate electrode 17 of each vertical MOSFET according to this invention faces the p-type epitaxial layer 12 through the gate oxide film 16 and also partially faces the buried n-type region 13 through the gate oxide film 16.

If a predetermined threshold (V_{T}) can be accomplished only by the p-type epitaxial layer 12, the structure shown in FIG. 3 may not be modified. However, if such a predetermined threshold (V_{T}) can not be accomplished only by the p-type epitaxial layer 12 or any other threshold than the predetermined threshold (V_{T}) is required, a p+-type base layer may be formed in the p-type epitaxial layer 12. In this case, ion implantation is carried out to control or adjust threshold (V_{T}). Such formation of the p+-type base layer also serves to improve backgate contactability and a permissible amount against an L-load (inductive load).

After the formation of the gate electrodes 17, source regions 18 of n+-type are formed in the surface of the p-type epitaxial layer 12 so as to be in contact with the corresponding gate oxide films 16, respectively. In the illustrated example, arsenic (As) of 1E15 to 1E16 atoms/cm² is ion-implanted to form the source regions 18.

Then, as shown in FIG. 4, an interlayer insulation film 19 is deposited and then subjected to predetermined patterning using a contact resist. Further, aluminum (Al) is deposited by sputtering and patterned into source electrodes 20. Thus, the vertical MOSFETs according to this invention are completed. The source electrodes 20 are patterned at outer peripheries of a chip, but are not patterned in the element regions.

In the MOSFET having the foregoing structure, when a reverse bias is applied between the drain (11) and source (20) at the time of BVDSS measurement, a depletion layer extends to the side of the p-type epitaxial layer 12 (p-type base layer). This is because the buried insulating film 15 is extended within the trench 14 to a region opposed to the buried n-type region 13 formed at the bottom of the trench 14.

Further, in the illustrated MOSFET according to this invention, the gate electrode 17 deeply extends into the trench 14, i.e. to the position opposed to the buried n-type region 13. This means that the gate electrode 17 and the buried n-type region 13 face each other. This shows that, when a positive voltage is applied to the gate electrode 17, an accumulation layer is formed within the buried n-type region 13 at a region that faces the gate electrode 17. On the other hand, the application of the positive voltage causes an inversion layer to be formed in the channel forming region facing the gate electrode 17, so that a channel layer is formed. Therefore, when the MOSFET is turned on, the accumulation layer in the buried n-type region 13 and the channel layer in the p-type epitaxial layer 12 are formed between the n+-type substrate 11 and the n+-type source region 18, thereby forming the current path.

That is, in this structure, since the accumulation layer is formed in the buried n-type region 13, there is no resistance component of the n-type epitaxial layer which conventionally exists. Therefore, in the MOSFET according to this invention, the on-resistance Ron can be minimized due to a reduction in channel resistance (increase in channel width) by miniaturization, a reduction in resistance by the accumulation layer in the buried n-type region 13, and further a reduction in resistance of the n+-type substrate 11. According to a test, there was obtained a vertical MOSFET having a BVDSS of 30 to 50V and an on-resistance Ron of about several mΩ.

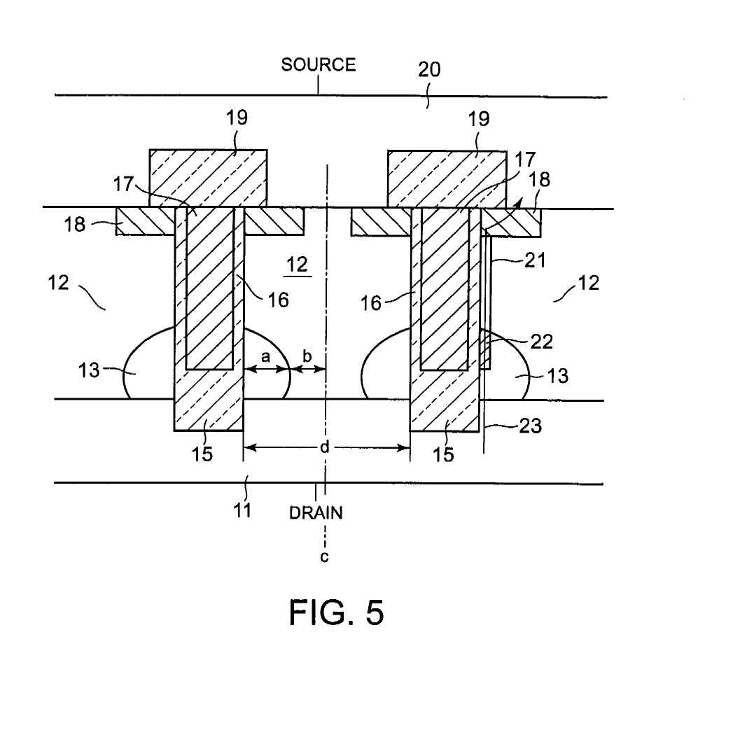

Now, referring to FIG. 5, the operation of the semiconductor device according to the first exemplary embodiment of this invention will be described in detail. In FIG. 5, the trenches 14 are formed at a predetermined distance d therebetween and the MOSFETs are provided at the trenches 14, respectively. Each trench 14 passes through the p-type epitaxial layer 12 and the buried n-type region 13 to reach the n+-type substrate 11. Further, each buried n-type region 13 is formed so as not to exceed a center line c between the adjacent trenches 14. Provided that the dimension of a maximum-width portion of a profile of each buried n-type region 13 is a and the length from the maximum-width portion to the center line c is b, the buried n-type region 13 is formed so that a and b are substantially equal to each other. Therefore, in the illustrated example, the dimension a of each buried n-type region 13 is substantially equal to a quarter of the predetermined distance d. Further, it is preferable that the impurity concentrations of each buried n-type region 13 and the p-type epitaxial layer 12 be substantially equal to each other.

When a positive voltage is applied to the gate electrode 17 of the illustrated MOSFET, a channel layer 21 is formed in the region, facing the gate electrode 17, of the p-type epitaxial layer 12. In this event, since the gate electrode 17 also partially faces the buried n-type region 13, an accumulation layer 22 is formed in the region, facing the gate electrode 17, of the buried n-type region 13. Therefore, when the MOSFET is turned on, a current path 23 comprising the n+-type substrate 11, the buried n-type region 13, the accumulation layer 22 of the buried n-type region 13, the channel layer 21, and the source region 18 is formed between the n+-type substrate 11 and the source region 18. In this manner, since the gate electrode 17 partially faces the buried n-type region 13, the accumulation layer 22 having an extremely small resistance is formed in the buried n-type region 13. Consequently, the MOSFET according to this invention can minimize the on-resistance Ron.

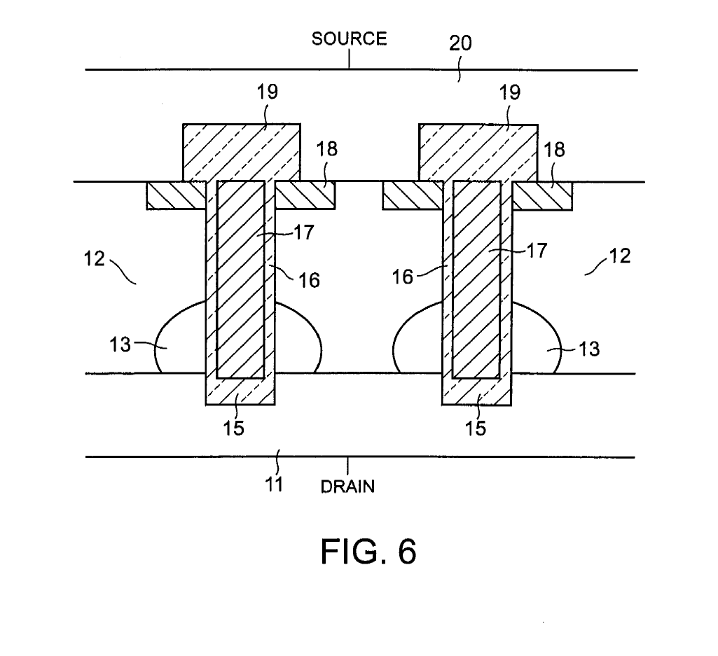

Referring to FIG. 6, a description will be given of a MOSFET according to a second exemplary embodiment of this invention. Herein, there is shown a structure of a MOSFET having a relatively low rated BVDSS. As shown in FIG. 6, while a thick buried insulating film 15 is formed at the bottom of each trench 14, the buried insulating film 15 shown in FIG. 6 is formed thinner than the buried insulating film 15 of the MOSFET shown in FIG. 4. Accordingly, polysilicon serving as each gate electrode 17 is formed so as to reach an n+-type substrate 11. With this structure, it is possible to increase the length of a region where the gate electrode 17 faces a buried n-type region 13. Therefore, when the MOSFET is turned on, the length of an accumulation layer in the buried n-type region 13 can be made longer. Consequently, as compared with the MOSFET shown in FIG. 4, it is possible to further reduce the resistance in the buried n-type region 13, thereby enabling a further reduction in on-resistance Ron.

While the description has been given of only the n-channel MOSFETs in the foregoing first and second exemplary embodiments, this invention is also similarly applicable to p-channel MOSFETs.

The low breakdown voltage MOSFETs according to this invention are applicable not only to switches or the like in automobile electronic devices, but also to protection circuits of lithium batteries, DC/DC converters for personal computers, and so on.

Finally, description will be made about any other modes or features according to this invention than the first mode mentioned before.

According to a second mode of this invention, there is obtained a semiconductor device, wherein, in the first mode, the gate electrode is extended to a depth reaching the substrate.

According to a third mode of this invention, there is obtained a semiconductor device, wherein, in the first or second mode, the semiconductor layer and the buried region form a super junction.

According to a fourth mode of this invention, there is obtained a semiconductor device, wherein, in any of the first to third modes, the gate insulation film has a side wall portion on a side wall of the trench and a bottom portion on a bottom of the trench. The bottom portion of the gate insulation film is thicker than the side wall portion of the gate insulation film.

According to a fifth mode of this invention, there is obtained a semiconductor device, wherein, in any of the first to fourth modes, the first conductivity type and the second conductivity type are n-type and p-type, respectively.

According to a sixth mode of this invention, there is obtained a semiconductor device, wherein, in any of the first to fourth modes, the first conductivity type and the second conductivity type are p-type and n-type, respectively.

According to a seventh mode of this invention, there is obtained a semiconductor device, wherein, in any of the first to sixth modes, the semiconductor layer is formed by an epitaxial layer while the buried region is formed by ion implantation.

According to an eighth mode of this invention, there is obtained a semiconductor device, wherein, in any of the first to seventh modes, the semiconductor layer and the buried region have an impurity concentration substantially equal to that of the buried region.

According to a ninth mode of this invention, there is obtained a semiconductor device comprising a plurality of vertical MOSFETs, wherein each of the vertical MOSFETs comprises a substrate of a first conductivity type, a semiconductor layer of a second conductivity type opposite to the first conductivity type on the substrate, a buried region of the first conductivity type formed on a boundary between the substrate and the semiconductor layer, a trench that passes through the semiconductor layer and the buried region and that reaches the substrate, a gate insulation film formed in the trench, and a gate electrode surrounded by the gate insulation film. The gate electrode has a portion faced with the semiconductor layer through the gate insulation film and a portion faced with the buried region through the gate insulation film.

According to a tenth mode of this invention, there is obtained a semiconductor device, wherein, in the ninth mode, the plurality of vertical MOSFETs are formed in a region which includes the trenches arranged at a predetermined distance spaced between adjacent ones of the trenches.

According to an eleventh mode of this invention, there is obtained a semiconductor device, wherein, in the tenth mode, a profile of the buried region in the semiconductor layer has a portion substantially equal to a quarter of the predetermined distance.

According to a twelfth mode of this invention, there is obtained a semiconductor device manufacturing method comprising a step of forming, on a substrate of a first conductivity type, a semiconductor layer of a second conductivity type different from the first conductivity type, a step of forming a buried region of the first conductivity type at a boundary between the substrate and the semiconductor layer, a step of forming a trench passing through the semiconductor layer and the buried region to reach the substrate, a step of forming an insulating film on an inner side of the trench, and a step of forming a gate electrode in the trench so as to be surrounded by the insulating film, the gate electrode having a portion partially facing the buried region.

According to a thirteenth mode of this invention, there is obtained a semiconductor device manufacturing method, wherein, in the twelfth mode, the step of forming the insulating film in the trench comprises a step of forming a bottom insulating film at a bottom of the trench and a step of forming a side-wall insulating film on a side wall of the trench, the side-wall insulating film being thinner than the bottom insulating film.

According to a fourteenth mode of this invention, there is obtained a semiconductor device manufacturing method, wherein, in the twelfth or thirteenth mode, the step of forming the buried region is a step of forming the buried region by ion implantation.

In this invention, since there exist the buried insulating film at the bottom of the trench and the buried n-type region, the depletion layer extends to the side of a semiconductor layer, i.e. the epitaxial layer, at the time of BVDSS measurement and, therefore, it is possible to obtain a semiconductor device having a high BVDSS. Further, since the gate electrode is formed so as to partially face the buried region, the accumulation layer is formed in the buried region at the time of on-resistance Ron measurement and, therefore, the on-resistance Ron can be minimized utilizing a low resistance of the accumulation layer.

What is claimed is:

1. A semiconductor device comprising:
a substrate of a first conductivity type;
a semiconductor layer of a second conductivity type on the substrate;
a buried region formed on a boundary between the substrate and the semiconductor layer;
a trench that passes through the semiconductor layer and the buried region and that reaches to the substrate;
a gate insulation film on an inside of the trench; and a gate electrode surrounded by the gate insulation film in the trench;
the gate electrode having a portion faced with the semiconductor layer through the gate insulation film and a portion faced with the buried region through the gate insulation film.

2. A semiconductor device as claimed in claim 1, wherein the gate electrode is extended to a depth reaching to the substrate.

3. A semiconductor device as claimed in claim 1, wherein the semiconductor layer and the buried region form a super-junction structure.

4. A semiconductor device as claimed in claim 1, wherein the gate insulation film has a side wall portion on a side wall of the trench and a bottom portion on a bottom of the trench, the bottom portion being thicker than the side wall portion.

5. A semiconductor device as claimed in claim 1, wherein the first and the second conductivity types are an n-type and a p-type, respectively.

6. A semiconductor device as claimed in claim 1, wherein the first and the second conductivity types are a p-type and an n-type, respectively.

7. A semiconductor device as claimed in claim 1, wherein the semiconductor layer is formed by an epitaxial layer while the buried region is formed by ion implantation.

8. A semiconductor device as claimed in claim 1, wherein the semiconductor layer has an impurity concentration substantially equal to that of the buried region.

9. A semiconductor device comprising a plurality of vertical MOSFET's, each of which comprises:
a substrate of a first conductivity type;
a semiconductor layer of a second conductivity type on the substrate;
a buried region formed on a boundary between the substrate and the semiconductor layer;
a trench that passes through the semiconductor layer and the buried region and that reaches to the substrate;
a gate insulation film on an inside surface of the trench; and
a gate electrode surrounded by the gate insulation film in the trench;
the gate electrode having a portion faced with the semiconductor layer through the gate insulation film and a portion faced with the buried region through the gate insulation film.

10. A semiconductor device as claimed in claim 9, wherein the plurality of the vertical MOSFET's are formed in a region which includes the trenches arranged at a predetermined distance spaced between adjacent ones of the trenches.

11. A semiconductor device as claimed in claim 10, wherein each of the buried regions has a profile within the semiconductor layer, the profile including a portion substantially equal to a quarter of the predetermined distance.

12. A method of manufacturing a semiconductor device, comprising the steps of:
forming, on a substrate of a first conductivity type, a semiconductor layer of a second conductivity type different from the first conductivity type;
forming a buried region of the first conductivity type at a boundary between the substrate and the semiconductor layer;
forming a trench passing through the semiconductor layer and the buried region to reach the substrate;
forming an insulating film on an inner side of the trench; and
forming a gate electrode in the trench so as to be surrounded by the insulating film, the gate electrode having a portion partially facing the buried region.

13. A method as claimed in claim 12, wherein the step of forming the insulating film in the trench comprises the steps of:
forming a bottom insulating film at a bottom of the trench and
forming a side-wall insulating film on a side wall of the trench, the side-wall insulating film being thinner than the bottom insulating film.

14. A method as claimed in claim 12, wherein the step of forming the buried region is a step of forming the buried region by ion implantation.
